(19) United States
(12) Patent Application Publication
(10) Pub. No.: US 2023/0395438 A1
(43) Pub. Date: Dec. 7, 2023

(54) SEMICONDUCTOR DEVICE INCLUDING SELECT DIES OF KNOWN THICKNESSES

(71) Applicant: WESTERN DIGITAL TECHNOLOGIES, INC., San Jose, CA (US)

(72) Inventors: Nagesh Vodrahalli, Los Altos, CA (US); Chih Yang Li, Menlo Park, CA (US); Xuyi Yang, Shanghai (CN); Cong Zhang, Shanghai (CN)

(73) Assignee: WESTERN DIGITAL TECHNOLOGIES, INC., San Jose, CA (US)

(21) Appl. No.: 17/831,810

(22) Filed: Jun. 3, 2022

(51) Int. Cl. H01L 21/66; H01L 25/065; H01L 23/00

(52) U.S. Cl. CPC H01L 22/20; H01L 25/0652; H01L 24/48; H01L 2225/06506; H01L 2225/0651; H01L 2225/06593; H01L 2224/48225; H01L 2924/1438; H01L 2924/37001; H01L 2924/1011; H01L 2924/182; H01L 2924/1431; H01L 2224/48148; H01L 2225/06562

(57) ABSTRACT

A semiconductor device includes a die stack having dies selected into the stack based on their thicknesses. After the dies are formed on a wafer and thinned, a metrology tool is used to determine the thicknesses of the dies in the wafer. These thicknesses are stored in a known thickness die (KTD) map, along with other information such as their standard and average deviations and their classification into a binning class. In one example, dies which have been classified into bin 1 (having an optimal thickness) are selected to provide a high capacity highly reliable semiconductor device. In a further example, dies of different bins are mixed and matched to provide a uniform, highly controlled overall die stack height.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, cellular telephones and SSDs (Solid State Drives).

Semiconductor memory may be provided within a semiconductor package, which protects the semiconductor memory and enables communication between the memory and a host device. Examples of semiconductor packages include system-in-a-package (SiP) or multichip modules (MCM), where a plurality of dies are mounted and interconnected on a small footprint substrate.

Semiconductor dies are typically batch processed together in a semiconductor wafer. Once the integrated circuits have been defined on the individual dies, the semiconductor wafer is thinned, typically with a grinding wheel in a so-called backgrind process. While the grinding process is highly controlled, slight variations in the thicknesses of the dies in the wafer occur across the wafer owing to tolerances in the backgrind process. These slight thickness variations can affect die performance. For example, dies having a silicon substrate layer which becomes too thin can have electrical performance issues, including premature degradation in the ability to erase stored data, as well as the leakage of the applied power supply current. A single such die in a die stack can impair performance of the entire package and adversely effect package yields.

It is also important to closely control the overall height of a die stack within a package. Even slight variations in die thickness can compound to significant variations in the overall die stack height, especially in modern day packages having many stacked dies.

### DESCRIPTION OF THE DRAWINGS

FIG. 1 is a flowchart for forming a wafer with semiconductor dies and laser grooves according to embodiments of the present technology.

FIG. 2 is a front view of a semiconductor wafer showing a first major surface of the wafer according to embodiments of the present technology.

FIG. 3 illustrates a stealth dicing before grinding laser process for dicing the semiconductor wafer according to embodiments of the present technology.

FIG. 4 illustrates a backgrind process for thinning the wafer and completing the stealth dicing process according to embodiments of the present technology.

FIG. 5 is a representation of a wafer map showing thicknesses of the silicon layers of semiconductor dies according to embodiments of the present technology.

FIG. 6 is a representation of a wafer map showing die thickness bin categories according to embodiments of the present technology.

FIG. 7 is a representation of a wafer map showing overall die thicknesses according to embodiments of the present technology.

FIG. 8 is a perspective view of a semiconductor die according to embodiments of the present technology.

FIG. 9 is a side view of a completed semiconductor package including semiconductor dies of selected thicknesses according to embodiments of the present technology.

FIG. 10 is a side view of a completed semiconductor package including semiconductor dies of selected thicknesses according to further embodiments of the present technology.

FIG. 11 is a schematic illustration of a computer for implementing aspects of the present technology.

### DETAILED DESCRIPTION

The present technology will now be described with reference to the figures, which in embodiments, relate to a semiconductor device, and method of forming same, including a die stack having dies selected into the stack based on their thicknesses. After the dies are formed on the wafer and thinned, a metrology tool is used to determine the thicknesses of the dies in the wafer. These thicknesses are stored in a known thickness die (KTD) map, along with other information such as their standard and average deviations and their classification into a binning class.

After dicing from the wafer, dies may be selected into a die stack of a semiconductor device based on their thickness. In one embodiment, dies which have been classified into bin 1 (having an optimal thickness) are selected to provide a high capacity highly reliable semiconductor device. In a further embodiment, dies of different bins are mixed and matched to provide a uniform, highly controlled overall die stack height.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±1.5 mm, or alternatively, ±2.5% of a given dimension.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other. When a first element is referred to as being directly connected, affixed, mounted or coupled to a second element, then there are no intervening elements between the first and second elements (other than possibly an adhesive or melted metal used to connect, affix, mount or couple the first and second elements).

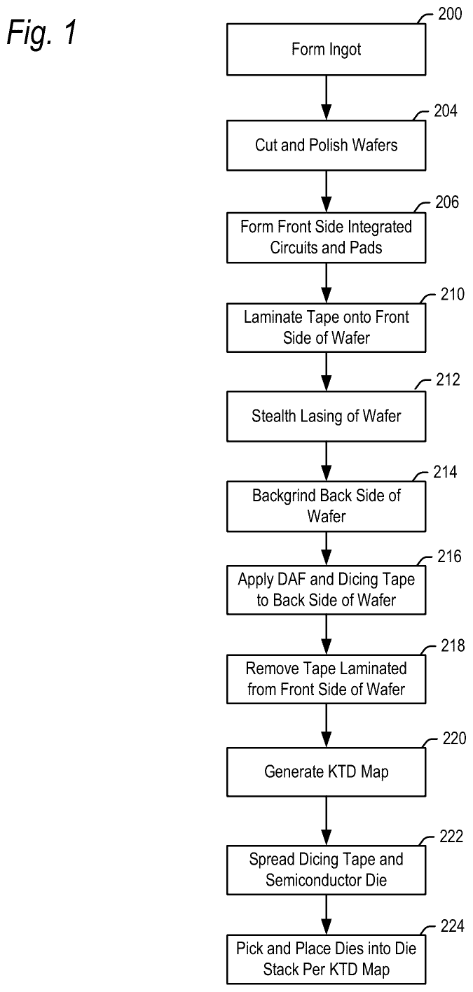

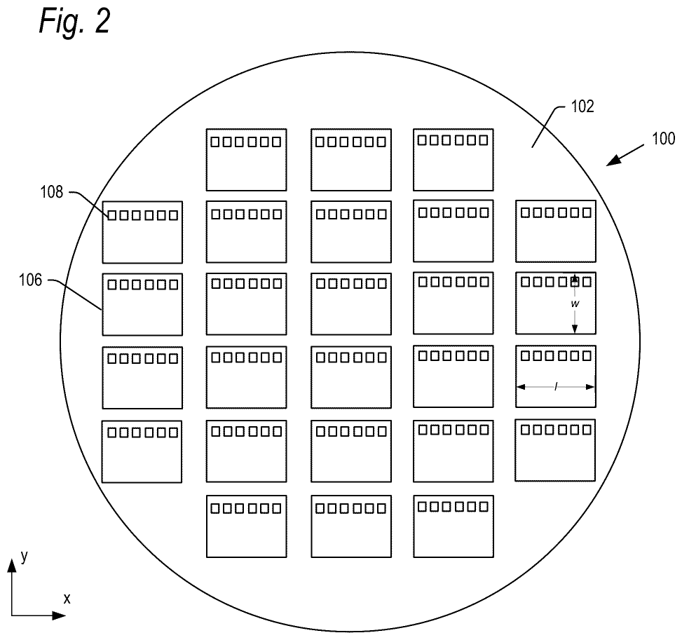

An embodiment of the present technology will now be explained with reference to the flowchart of FIG. 1, and the views of FIGS. 2-10. Referring initially to the flowchart of FIG. 1, a semiconductor wafer 100 may start as an ingot of wafer material which may be formed in step 200. In one example, the ingot from which the wafers 100 are formed may be monocrystalline silicon grown according to either a Czochralski (CZ) or floating zone (FZ) process. However, wafer 100 may be formed of other materials and by other processes in further embodiments.

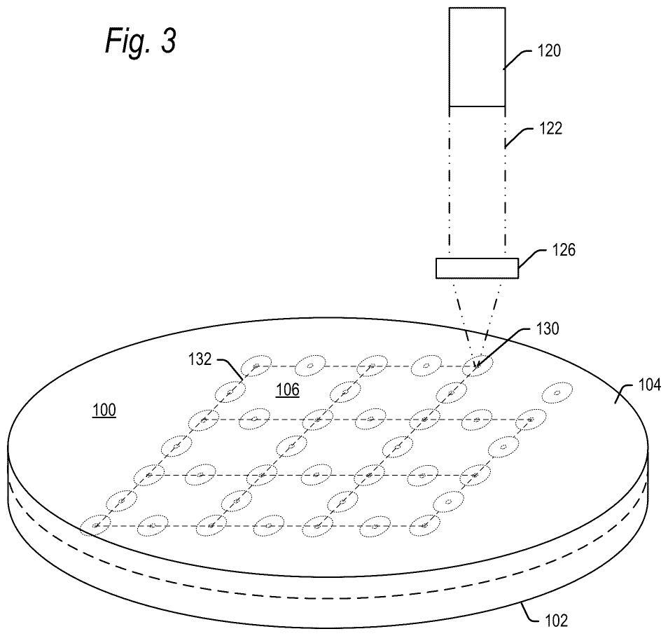

In step 204, the semiconductor wafer 100 may be cut from an ingot and polished on both the first major surface 102 (FIG. 2), and second major surface 104 (FIG. 3) opposite surface 102, to provide smooth parallel surfaces. In step 206, the first major surface 102 may undergo various processing steps to divide the wafer 100 into respective semiconductor dies 106 (one of which is numbered in FIGS. 2 and 3), and to form integrated circuits of the respective semiconductor dies 106 in active areas of the dies on and/or in the first major surface 102. These various processing steps may include photolithographic steps, etching steps and metallization steps depositing metal layers, vias and contacts for transferring signals to and from the integrated circuits. The electrical contacts may include die bond pads 108 (one of which is numbered in FIG. 2) exposed on the first major surface 102. The resulting semiconductor dies 106 include an integrated circuit layer at the first major surface 102 formed over a silicon substrate layer which extends to the second major surface 104.

As shown in FIG. 2, the semiconductor dies 106 may have length, l, along the x-direction and a width, w, in the y-direction. The length l of the semiconductor dies is longer than the width w of the semiconductor dies. The die bond pads 108 may be formed along one of the long edges of the semiconductor dies 106.

The number of semiconductor dies 106 shown on wafer 100 in FIGS. 2 and 3 is for illustrative purposes, and wafer 100 may include more semiconductor dies 106 than are shown. Similarly, the number of bond pads 108 shown on each semiconductor die 106 on wafer 100 in FIG. 2 is for illustrative purposes, and each die 106 may include more die bond pads than are shown. The die bond pads 108 may for example be formed of aluminum, or alloys thereof, but the pads 108 may be formed of other materials in further embodiments. In embodiments, the integrated circuits may be configured as flash memory such as 2D NAND flash memory or 3D BiCS (Bit Cost Scaling), V-NAND or other 3D flash memory, though other types of integrated circuits are contemplated.

After formation of the integrated circuits of each semiconductor die, a layer of tape may be laminated onto the major surface 102 in step 210. The wafer 100 may then be turned over, and diced in step 212. Embodiments of the present technology dice the wafer 100 using a stealth dicing before grind (SDBG) step, as shown in FIG. 3. The wafer 100 may be supported on a chuck or other support surface (not shown) with the taped first major surface 102 resting against the support surface and the second major surface 104 exposed. A laser 120 may then emit a pulsed laser beam 122 at a wavelength that transmits through the second major surface 104 of the wafer 100, for example at infrared or near-infrared wavelengths. The pulsed laser beam may be focused to a point beneath the wafer's surface 104 using an optical system, for example including one or more collimating lenses 126. When the laser beam hits a peak power density at the focal point, the wafer absorbs the energy, and a pinpoint hole 130 is created beneath the wafer's surface.

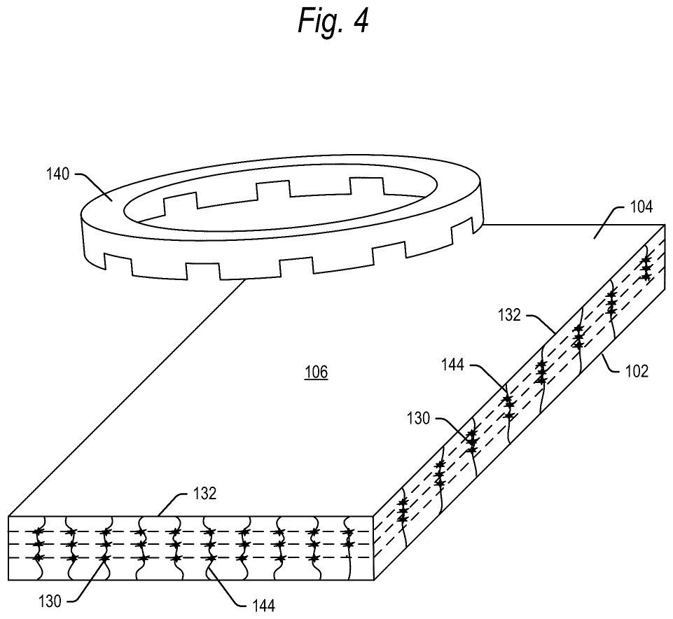

The laser may be moved along scribe lines 132 in a plane of the wafer and activated at a number of points so that a number of closely situated pinpoint holes 130 are formed at an intermediate depth of the wafer (between the first and second major surfaces 102, 104 of the wafer). The rows and columns of pinpoint holes 130 define the eventual shape and outline of each semiconductor die 106 to be diced from wafer 100 as indicated in FIG. 3. The laser may form multiple layers of pinpoint holes 130 at multiple depths as shown in FIG. 4, but there may be a larger or smaller number of layers in further embodiments. While SDBG has been described for dicing the wafer 100, it is understood that the wafer 100 may be diced by other technologies in further embodiments, including by dicing blade.

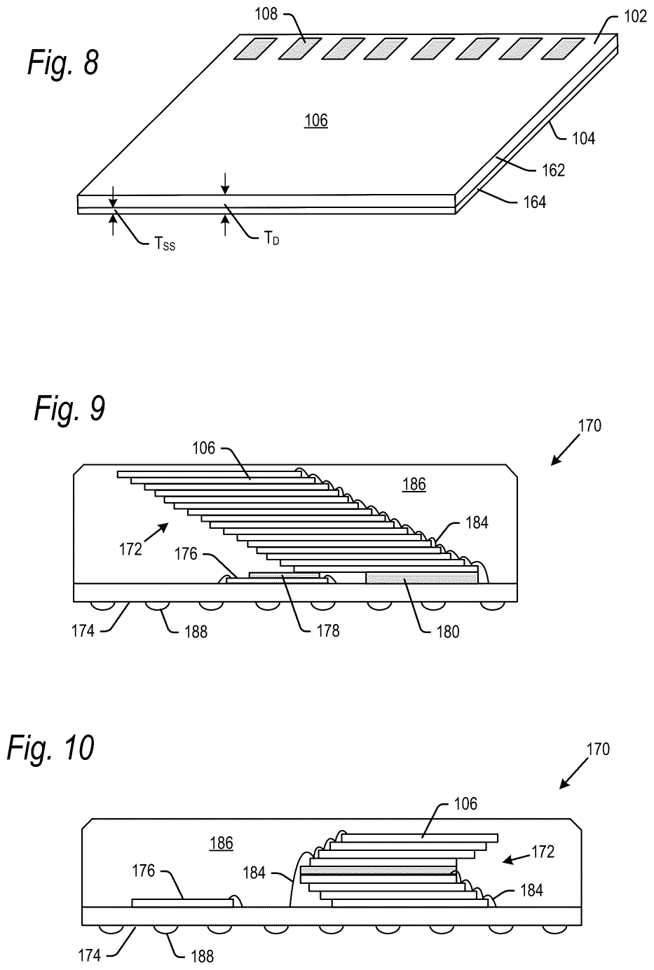

After the stealth lasing step 212, the wafer 100 may be completely diced, or one or more semiconductor die 106 still be affixed together. The wafer may then be thinned in step 214 using a grinding wheel 140 (FIG. 4) applied to the second major surface 104. The grinding wheel 140 may thin the wafer 100 from, for example, 780 μm to its final thickness of for example about 25 μm to 36 μm. It is understood that the wafer 100 may be thinner or thicker than this range after the backgrind step in further embodiments. As shown in FIG. 8, in addition to thinning the wafer 100, the vibrations from the backgrind wheel 140 may cause cracks 144 at the pinpoint holes 130 to propagate along crystalline planes toward the first and second major surfaces 102, 104 of the wafer 100 to complete the dicing of any die along scribe lines 132 that may have remained connected after stealth lasing step 212.

While FIG. 4 appears to show a diced semiconductor die 106 for illustrative purposes, the dies 106 may still be part of wafer 100 while the stealth lasing process is performed (and pinpoint holes 130 would not in fact be visible to the eye when inspecting wafer 100).

After completion of the backgrind step 214, a layer of die attach film (DAF) adhered to a flexible dicing tape may be applied to the second major surface 104 of the wafer 100 in step 216. The wafer 100 may then be turned over and supported on a chuck or other support surface, and the lamination tape on the first major surface 102 of the wafer 100 may be removed in step 218.

As noted in the Background section, owing to tolerances in the operation of the backgrind wheel 140, the thicknesses of dies 106 across the wafer 100 may vary. As one example, the thicknesses of the silicon substrate layer on which the integrated circuit layer is formed may vary as much as 4 μm to 5 μm (or more) from die to die, and the overall thicknesses of the dies 106 may vary as much as 4 μm to 5 μm (or more) from die to die. In accordance with aspects of the present technology, a known thickness die (KTD) map of the wafer 100 may be generated in step 220 with data of die thicknesses, and the KTD map may then be used when selecting dies 106 from the wafer 100 for pick and place into a die stack as explained below.

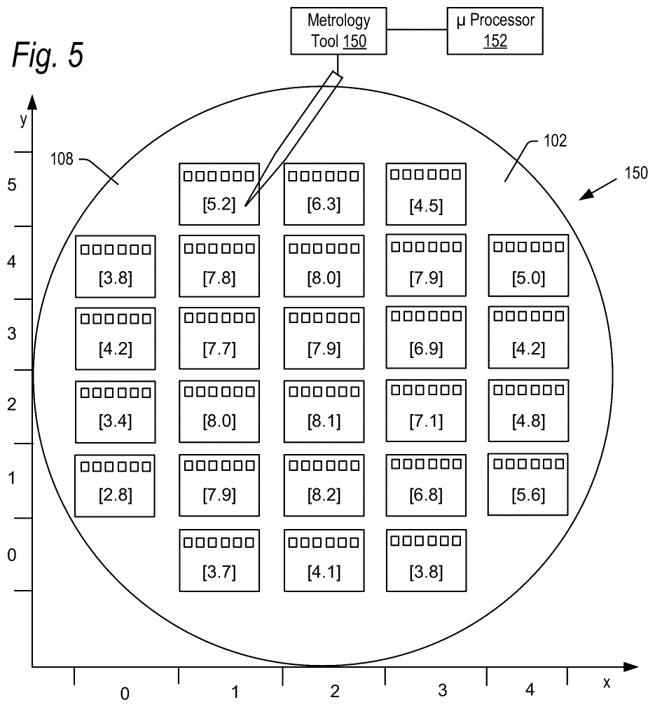

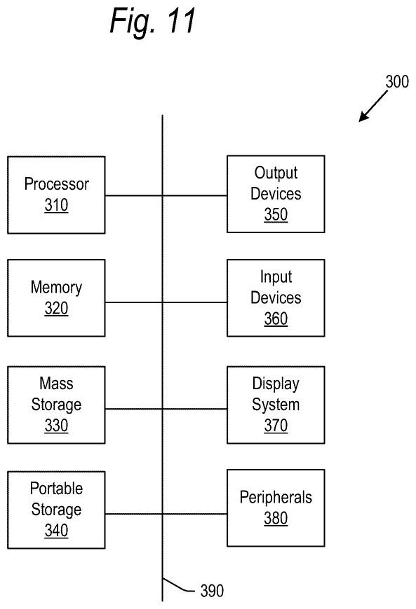

Step 220 of generating a KTD map begins with measuring die thicknesses across wafer 100 using a wafer thickness metrology tool 150 (shown schematically in FIGS. 5 through 7). Metrology tool 150 can for example measure the thicknesses of the silicon substrate layers in very high spatial resolution data of all semiconductor dies 106 across the diced wafer. The metrology tool is capable of capturing thickness data at a large number of data points across the wafer, for example capturing thickness data at multiple points on each semiconductor die 106. The measured silicon substrate thickness for each die 106 may then be stored within a computer 152 (details of which are provided below with respect to FIG. 11).

FIGS. 5 through 7 are three examples of KTD maps 160 which may be generated in step 220. Such maps are graphic representations of the wafer map data that is stored within memory of computer 152. As shown, the location of each semiconductor die 106 may be mapped to a location and identified on wafer 100, which identification is stored within the computer memory in association with data for each die 106. FIGS. 5 through 7 show a Cartesian coordinate system for uniquely identifying each die 106 on wafer 100. For example, the semiconductor die in the bottom row at the left may be identified using the x, y coordinates [1, 0]. However, a wide variety of other identification schemes may be used to identify and map each of the dies 106 on wafer 100. Also, as noted, the number of dies 106 shown on the wafer 100 and wafer maps 160 are by way of example only, and the actual wafer 100 and map 160 may have many more dies than is shown.

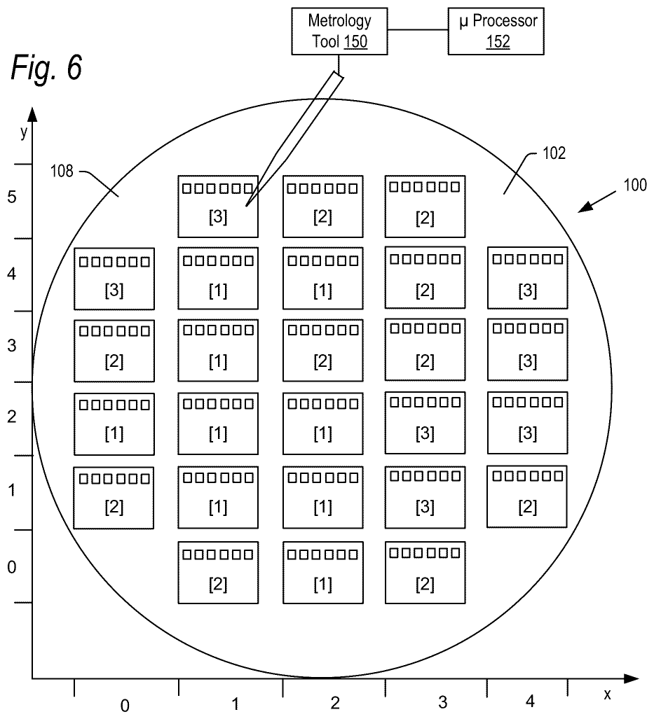

In FIG. 5, the data that is stored in association with each semiconductor die 106 in the KTD map is the actual measured thickness of the silicon substrate layer of each die. In further embodiments, each of the dies 106 may be classified by computer 152 into a binning category based on the measured thicknesses of the silicon substrate layer. In FIG. 6, the data that is stored in association with each semiconductor die 106 in the KTD map is the assigned binning classification of each die. As noted in the Background section, the thickness of the silicon substrate layer may impact the electrical performance of a semiconductor die. The computer 152 may store rules for assigning a binning classification to each of the dies on wafer 100 based on their thicknesses. For example, dies having an optimal silicon substrate layer thickness (such as for example 7.0 μm to 8.0 μm) may be classified into bin 1. Dies having a good but slightly less optimal silicon substrate layer thickness (such as for example 6.0 μm to 6.9 μm) may be classified into bin 2. The remainder of the dies may be similarly classified into bins 3, 4 and 5 (or more) based on the thickness of their silicon substrate layers.

The computer 152 may store both the thickness of the silicon substrate layers and the binning classification. The computer 152 may also determine and store additional data relating to the silicon substrate layer thickness of dies 106 across wafer 100, including the average and standard deviations of the silicon substrate layer thicknesses of the dies 106 on wafer 100.

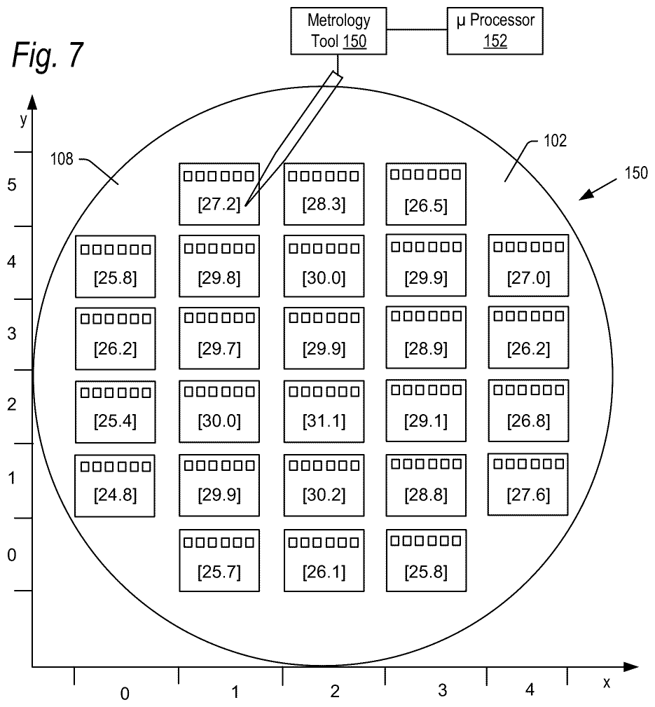

The KTD maps of FIGS. 5 and 6 may be used to pick dies 106 into a die stack of a semiconductor device to optimize electrical performance of the semiconductor device as explained below. In a further embodiment, instead of picking dies into a die stack to optimize electrical performance, dies 106 may be picked into a die stack to provide a known, highly controlled predefined overall height of the die stack. The metrology tool 150 may also measure overall die thicknesses of the dies in the wafer 100. FIG. 7 shows a KTD map 160 including these overall die thicknesses. The listed thicknesses are by way of example only and may vary in further embodiments. In examples, the KTD map 160 may store all of the information shown in FIGS. 5 through 7.

In the embodiments described above, the metrology tool measures the thickness of the silicon substrate layer and generates the KTD map in step 220 after the wafer has been flipped over and supported with the DAF layer and dicing tape facing the chuck in steps 216 and 218. In further embodiments, the metrology tool may measure the thickness of the silicon substrate layer and generate the KTD map 160 before the DAF layer and dicing tape are applied. So the KTD map can be created by the metrology tool after the DAF mount process, or created just after the wafer 100 is thinned.

After the KTD map 160 is generated and the wafer is supported with the flexible dicing tape facing the support chuck, the flexible dicing tape may be stretched along orthogonal axes to separate the individual semiconductor dies 106 in step 222 to allow the individual semiconductor dies 106 to be removed by a pick and place robot for inclusion in a semiconductor device. It is conceivable that the dies 106 are not fully diced at completion of the backgrind step 214. In this event, stretching of the dicing tape in step 222 will complete dicing of the semiconductor dies along the SDBG separation lines 114.

In accordance with aspects of the present technology, dies 106 may be selected by the pick and place robot and stacked on a substrate in a die stack based on their measured thicknesses and/or binning category, as shown in the KTD maps of FIGS. 5 through 7. In one embodiment, only those dies in bin 1 may be selected and mounted in the die stack to provide a finished semiconductor device having only the most optimally performing semiconductor dies. In further embodiments, only dies from bins 1 and 2 may be selected and mounted in the die stack of the semiconductor device. Depending on the number of semiconductor dies in the die stack, a single wafer may have enough dies from bin 1 (or bins 1 and 2) for multiple semiconductor devices. Once all of the dies from bins 1 and 2 have been picked and placed, dies from the lower bins may then be picked and placed into a die stack of the semiconductor device. While not including the optimally performing dies, a semiconductor device including the dies from the lower bins is still sufficient and useful for a number of end use scenarios.

In a further aspect of the present technology, instead of picking dies into a die stack based on their bin classification, dies may be selected into a die stack to provide a uniform overall height of the die stack. As noted, in embodiments, the computer 152 may store the overall thicknesses of the dies in addition to or instead of the thicknesses of the silicon substrate layer, as shown in the KTD map of FIG. 7. In such embodiments, the computer 152 may select dies for pick and place into the die stack so that the total height of the die stack after all dies are mounted in the die stack is some predefined uniform height across multiple semiconductor devices.

In a further embodiment of the present technology, dies may be picked from a wafer and placed into a die stack based on considerations including both bin category and overall height of the die stack. In such embodiments, using the data from the KTD map, the computer 152 may first select dies from bins 1 and 2 for pick and place into a die stack, while at the same time selecting dies from bins 1 and 2 that together provide the desired predefined uniform overall die stack height.

FIG. 8 is a perspective view of a completed semiconductor die 106 diced from wafer 100. The die 106 includes an integrated circuit layer 162 formed over a silicon substrate layer 164. The silicon substrate layer 164 may have a thickness, T_{SS}, and the die 106 may have an overall die thickness, T_{D}. In embodiments, the thickness, T_{SS}, of the silicon substrate layer 164 may optimally be between 7 μm and 8 μm, but may be as small as 3 μm owing to tolerances in the backgrind process. In embodiments, the overall die thickness, T_{D}, may be a predefined thickness between 25 μm and 38 μm. However, again owing to tolerances in the backgrind process, the overall die thickness, T_{D}, may be at much as 5 μm (or more) less than the predefined overall die thickness. These thicknesses of the silicon substrate layer and overall die thickness are by way of example and may vary in further embodiments.

The semiconductor dies 106 are picked from the wafer 100 and placed into a semiconductor device in step 224. FIG. 9 is a side view of a completed semiconductor device 170 according to embodiments of the present technology. In the embodiment shown, the semiconductor device 170 includes sixteen semiconductor dies 106 picked from wafer 100 and placed into a die stack 172 which is built on top of a substrate 174. The dies are fixed within the die stack 172 and on substrate 174 using the DAF layer on the bottom of each die 106. A controller die 176 may be mounted to substrate 174, which in embodiments may be an ASIC for controlling the transfer of data to/from the dies 106 in stack 172. Spacers 178, 180 may be used over the controller die 176 and substrate 174 to provide a level base for the die stack 172.

The dies 106 may be electrically connected to each other and the substrate 174 using bond wires 184, though the dies 106 may be electrically connected to each other and the substrate 174 by other schemes in further embodiments including for example through silicon vias (TSVs). In order to leave room for the bond wires 184 to connect to the bond pads 108 on each semiconductor die 106 in stack 172, the dies 106 are stacked in a stepped offset from each other. In the embodiment of FIG. 9, all of the dies in the stack may be stepped offset in the same direction.

The dies 106, 176 and bond wires 184 may be encapsulated in a molding compound 186, which may for example be epoxy resin, Phenol resin, fused silica, crystalline silica, carbon black and/or metal hydroxide. Other molding compounds are contemplated. In embodiments, the semiconductor device 170 may be used as a BGA (ball grid array) package soldered to a host device such as a printed circuit board. In such embodiments, the semiconductor device 170 may further include solder balls 188 on a bottom surface of the substrate 174 for physically and electrically coupling the semiconductor device 170 to the host device. In further embodiments, the semiconductor device 170 may be used as an LGA (land grid array) package configured for insertion to and removal from a slot of a host device. In such embodiments, the solder balls 188 may be replaced with contact fingers (not shown) on a bottom surface of the substrate 174 for mating with pins in the host device slot.

It is understood that semiconductor device 170 may include other configurations and other numbers of semiconductor dies 106 in further embodiments. FIG. 10 is one such further embodiment including eight semiconductor dies 106 mounted on substrate 174. Further embodiments may include two, four, thirty-two, sixty-four or other numbers of semiconductor dies 106. In the embodiment of FIG. 10, the controller die 176 may be mounted on the substrate 174 next to the die stack 172, and the die stack 172 may be mounted directly to the substrate 174 without spacers. In order to minimize the overall footprint of die stack 172, the embodiment of FIG. 10 shows a first group of dies 106 in stack 172 having a stepped offset in a first direction, and a second group of dies 106 in stack 172 having a stepped offset in a second direction opposite the first direction. Bond wires 184 are shown off of two sides of the die stack 172 electrically coupling the first and second groups of dies 106 to each other and the substrate 174.

A wire embed film (WEF) layer 190 is shown separating the first and second groups of dies 106 to leave room for the wire bonds to the top die 106 in the first group of dies 106. The semiconductor device 170 may further include a controller die 176 and solder balls 188 as described above with respect to FIG. 9. Other configurations of semiconductor device 170 are contemplated.

In accordance with aspects of the present technology, the semiconductor dies 106 are picked from the wafer and placed into the die stack of FIGS. 9 and 10 in step 224 using the KTD map generated in step 220. For example, where dies are selected by their binning classification, all of the dies in stack 172 may come from bin 1, or from bins 1 and 2. To the extent there are sufficient bin 1, 2 dies for multiple semiconductor devices 170, the dies from bins 1, 2 may be selected into multiple semiconductor devices 170. Once those dies are exhausted, dies from other bins may be selected for placement into further semiconductor devices 170. The computer 152 (or other processing device) uses the stored locations of the desired dies on wafer 100 from the KTD map 160 to direct the pick and place robot when picking dies from wafer 100 for placement into the die stack 172.

As noted, in further embodiments, the KTD map may store actual thicknesses of the silicon substrate layers 164 of the dies 106 on wafer 100. Where dies are selected for inclusion into a die stack 172 by their silicon substrate thickness listed in the KTD map 160, all of the dies in stack 172 may have silicon substrate layer thicknesses above some predefined threshold. In one example, that predefined threshold may be 7.0 μm, but the predefined threshold may be higher or lower than that in further embodiments. Once the dies having the optimal silicon substrate layer thicknesses are exhausted, dies having silicon substrate layer thicknesses below the predefined threshold may be selected for placement into further semiconductor devices 170.

As noted above, dies 106 may alternatively or additionally be selected for placement into a die stack using the data from the KTD map taking into consideration the overall height of the die stack 172. For example, in the embodiment of FIG. 9 including sixteen dies, differences in die thicknesses of as much as 5 μm per die can result in overall stack height fluctuations of as much as 80 μm (which may be the thickness of approximately three semiconductor dies 106). In order to avoid this stack height fluctuation, the computer 152 may group dies together using the overall die thickness data from the KTD map to ensure that each group of dies adds up to a desired predefined height for die stack 172.

Thus, for the embodiment of FIG. 9, the computer 152 may divide the wafer 100 into multiple groups each having sixteen dies, with the total height of the sixteen dies in each group adding to some predefined desired overall height of the die stack 172. In further embodiments, it is contemplated die stacks for different semiconductor devices 170 each have the same height, but include different numbers of semiconductor dies. Thus, the computer 152 may devise a first group of sixteen dies adding to the predefined desired die stack height for a first semiconductor device 170, while devising a second group of more than sixteen (relatively thinner) dies adding to the predefined desired die stack height for a second semiconductor device 170.

FIG. 11 illustrates details of a computing system 300 used to implement embodiments of the present technology that may for example be computer 152 described above. The computing system 300 of FIG. 11 includes one or more processors 310 and main memory 320. Main memory 320 stores, in part, instructions and data for execution by processor unit 310. Main memory 320 can store the executable code when the computing system 300 is in operation. The computing system 300 of FIG. 11 may further include a mass storage device 330, portable storage medium drive(s) 340, output devices 350, user input devices 360, a display system 370, and other peripheral devices 380.

The components shown in FIG. 11 are depicted as being connected via a single bus 390. The components may be connected through one or more data transport means. Processor unit 310 and main memory 320 may be connected via a local microprocessor bus, and the mass storage device 330, peripheral device(s) 380, portable storage medium drive(s) 340, and display system 370 may be connected via one or more input/output (I/O) buses.

Mass storage device 330, which may be implemented with a magnetic disk drive or an optical disk drive, is a non-volatile storage device for storing data and instructions for use by processor unit 310. Mass storage device 330 can store the system software for implementing embodiments of the present technology for purposes of loading that software into main memory 320.

Portable storage medium drive(s) 340 operate in conjunction with a portable non-volatile storage medium, such as a floppy disk, compact disk or digital video disc, to input and output data and code to and from the computing system 300 of FIG. 11. The system software for implementing embodiments of the present technology may be stored on such a portable medium and input to the computing system 300 via the portable storage medium drive(s) 340.

Input devices 360 provide a portion of a user interface. Input devices 360 may include an alpha-numeric keypad, such as a keyboard, for inputting alpha-numeric and other information, or a pointing device, such as a mouse, a trackball, stylus, or cursor direction keys. Additionally, the system 300 as shown in FIG. 11 includes output devices 350. Suitable output devices include speakers, printers, network interfaces, and monitors. Where computing system 300 is part of a mechanical client device, the output device 350 may further include servo controls for motors within the mechanical device.

Display system 370 may include a liquid crystal display (LCD) or other suitable display device. Display system 370 receives textual and graphical information, and processes the information for output to the display device.

Peripheral device(s) 380 may include any type of computer support device to add additional functionality to the computing system. Peripheral device(s) 380 may include a modem or a router.

The components contained in the computing system 300 of FIG. 11 are those typically found in computing systems that may be suitable for use with embodiments of the present technology and are intended to represent a broad category of such computer components that are well known in the art. Thus, the computing system 300 of FIG. 11 can be a personal computer, hand-held computing device, telephone, mobile computing device, workstation, server, minicomputer, mainframe computer, or any other computing device. The computer can also include different bus configurations, networked platforms, multi-processor platforms, etc. Various operating systems can be used including UNIX, Linux, Windows, Macintosh OS, Palm OS, and other suitable operating systems.

Some of the above-described functions may be composed of instructions that are stored on storage media (e.g., computer-readable medium). The instructions may be retrieved and executed by the processor. Some examples of storage media are memory devices, tapes, disks, and the like. The instructions are operational when executed by the processor to direct the processor to operate in accord with the invention. Those skilled in the art are familiar with instructions, processor(s), and storage media.

It is noteworthy that any hardware platform suitable for performing the processing described herein is suitable for use with the invention. The terms “computer-readable storage medium” and “computer-readable storage media” as used herein refer to any medium or media that participate in providing instructions to a CPU for execution. Such media can take many forms, including, but not limited to, non-volatile media, volatile media and transmission media. Non-volatile media include, for example, optical or magnetic disks, such as a fixed disk. Volatile media include dynamic memory, such as system RAM. Transmission media include coaxial cables, copper wire and fiber optics, among others, including the wires that comprise one embodiment of a bus. Transmission media can also take the form of acoustic or light waves, such as those generated during radio frequency (RF) and infrared (IR) data communications. Common forms of computer-readable media include, for example, a floppy disk, a flexible disk, a hard disk, magnetic tape, any other magnetic medium, a CD-ROM disk, digital video disk (DVD), any other optical medium, any other physical medium with patterns of marks or holes, a RAM, a PROM, an EPROM, an EEPROM, a FLASHEPROM, any other memory chip or cartridge, a carrier wave, or any other medium from which a computer can read.

Various forms of computer-readable media may be involved in carrying one or more sequences of one or more instructions to a CPU for execution. A bus carries the data to system RAM, from which a CPU retrieves and executes the instructions. The instructions received by system RAM can optionally be stored on a fixed disk either before or after execution by a CPU.

In summary, an example of the present technology relates to a semiconductor device, comprising: a substrate; and a die stack mounted on the substrate, the die stack comprising a first plurality of semiconductor dies, the first plurality of semiconductor dies selected from a wafer comprising a second plurality of semiconductor dies, two or more of the second plurality of semiconductor dies having at least portions of differing thicknesses, the first plurality of semiconductor dies selected from the second plurality of semiconductor dies based on dies having thicknesses of the at least portions of the semiconductor dies that provide desired electrical performance to the die stack.

In a further example, the present technology relates to a semiconductor device, comprising: a substrate; and a die stack mounted on the substrate, the die stack comprising a first plurality of semiconductor dies, the first plurality of semiconductor dies selected from a wafer comprising a second plurality of semiconductor dies, two or more of the second plurality of semiconductor dies having differing thicknesses, the first plurality of semiconductor dies selected from the second plurality of semiconductor dies based on an overall desired thickness of the die stack.

In another example, the present technology relates to a method of forming a semiconductor device, comprising: forming a plurality of semiconductor dies on a wafer; measuring thicknesses of the plurality of semiconductor dies on the wafer; storing on a computing system the measured thicknesses of the plurality of semiconductor dies on the wafer; picking a sub-group of the plurality of semiconductor dies for mounting in the semiconductor device, the sub-group picked based on the measured and stored thicknesses of the semiconductor dies in the sub-group.

In a still further example, the present technology relates to a semiconductor device, comprising: a substrate; and a die stack mounted on the substrate, the die stack comprising a first plurality of semiconductor dies, the first plurality of semiconductor dies selected from a wafer comprising a second plurality of semiconductor dies, two or more of the second plurality of semiconductor dies having at least portions of differing thicknesses, the first plurality of semiconductor dies selected from the second plurality of semiconductor dies using means for determining thicknesses of the at least portions of the second plurality of semiconductor dies.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a substrate; and
a die stack mounted on the substrate, the die stack comprising a first plurality of semiconductor dies, the first plurality of semiconductor dies selected from a wafer comprising a second plurality of semiconductor dies, two or more of the second plurality of semiconductor dies having at least portions of differing thicknesses, the first plurality of semiconductor dies selected from the second plurality of semiconductor dies based on dies having thicknesses of the at least portions of the semiconductor dies that provide desired electrical performance to the die stack.

2. The semiconductor device of claim 1, wherein the second plurality of semiconductor dies comprise silicon substrate layers over which integrated circuit layers are formed, and wherein the at least portions of the two or more semiconductor dies having differing thicknesses comprise the silicon substrate layers having differing thicknesses.

3. The semiconductor device of claim 1, wherein the first plurality of semiconductor dies are selected from the second plurality of semiconductor dies using a known thickness die (KTD) map of the second plurality of semiconductor dies in the wafer.

4. The semiconductor device of claim 3, wherein the KTD map categorizes thicknesses of semiconductor dies of the second plurality of semiconductor dies by categorizing the second plurality of semiconductor dies into binning categories comprising at least binning categories 1, 2 and 3.

5. The semiconductor device of claim 4, wherein the first plurality of semiconductor dies are all selected from binning category 1.

6. The semiconductor device of claim 4, wherein the first plurality of semiconductor dies are all selected from binning categories 1 and 2.

7. The semiconductor device of claim 3, wherein the second plurality of semiconductor dies comprise silicon substrate layers on which are formed integrated circuit layers, and wherein the KTD map includes thicknesses of the silicon substrate layers of the second plurality of semiconductor dies from the wafer.

8. The semiconductor device of claim 7, wherein the first plurality of semiconductor dies are all selected from semiconductor dies of the second plurality of semiconductor dies having s layers above a predefined thickness.

9. The semiconductor device of claim 1, wherein the first plurality of semiconductor dies comprise one of eight memory dies and sixteen memory dies.

10. The semiconductor device of claim 1, further comprising bond wires electrically coupling the first plurality of semiconductor dies to each other and the substrate.

11. The semiconductor device of claim 1, further comprising a controller die for controlling data transfer to and from the first plurality of semiconductor dies.

12. The semiconductor device of claim 11, further comprising a molding compound for encapsulating the die stack and the controller die.

13. A semiconductor device, comprising:
a substrate; and
a die stack mounted on the substrate, the die stack comprising a first plurality of semiconductor dies, the first plurality of semiconductor dies selected from a wafer comprising a second plurality of semiconductor dies, two or more of the second plurality of semiconductor dies having differing thicknesses, the first plurality of semiconductor dies selected from the second plurality of semiconductor dies based on an overall desired thickness of the die stack.

14. The semiconductor device of claim 13, wherein the first plurality of semiconductor dies are selected from the second plurality of semiconductor dies using a known thickness die (KTD) map of the second plurality of semiconductor dies in the wafer.

15. The semiconductor device of claim 14, wherein the KTD map includes thicknesses of the second plurality of semiconductor dies from the wafer.

16. The semiconductor device of claim 15, wherein the first plurality of semiconductor dies are selected based on combined thicknesses of the first plurality of semiconductor dies in the KTD adding up to the overall desired thickness of die stack.

17. The semiconductor device of claim 16, wherein the first plurality of semiconductor dies all have the same thicknesses.

18. The semiconductor device of claim 13, wherein the second plurality of semiconductor dies further comprise silicon substrate layers over which integrated circuit layers are formed, and wherein two or more of the second plurality of semiconductor dies have silicon substrate layers of differing thicknesses, the first plurality of semiconductor dies further selected from the second plurality of semiconductor dies based on dies having thicknesses of the silicon substrate layers that provide desired electrical performance to the die stack.

19. The semiconductor device of claim 18, wherein the first plurality of semiconductor dies are selected from the second plurality of semiconductor dies using a known thickness die (KTD) map of the second plurality of semiconductor dies in the wafer, the KTD including thicknesses of the second plurality of semiconductor dies from the wafer, and the KTD map including thicknesses of the silicon substrate layers of the second plurality of semiconductor dies from the wafer.

20. A method of forming a semiconductor device, comprising:
forming a plurality of semiconductor dies on a wafer;
measuring thicknesses of the plurality of semiconductor dies on the wafer;
storing on a computing system the measured thicknesses of the plurality of semiconductor dies on the wafer;
picking a sub-group of the plurality of semiconductor dies for mounting in the semiconductor device, the sub-group picked based on the measured and stored thicknesses of the semiconductor dies in the sub-group.
